(19) United States
(12) Patent Application Publication
(10) Pub. No.: US 2026/0307523 A1
(43) Pub. Date: Oct. 8, 2026

(54) IN-VEHICLE CUTOFF DEVICE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Gozo OZEKI, Yokkaichi-shi, Mie (JP)

(73) Assignees: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(21) Appl. No.: 19/481,374

(22) PCT Filed: May 9, 2023
(86) PCT No.: PCT/JP2023/017370

§ 371 Date: Nov. 4, 2025

(51) Int. Cl. B60L 53/62; B60L 53/16; B60L 58/25; B60R 16/033

(52) U.S. Cl. CPC B60L 53/62; B60L 53/16; B60L 58/25; B60R 16/033; B60L 2240/545

(57) ABSTRACT

An in-vehicle cutoff device is to be mounted in a vehicle including: a power storage unit and a conductive path provided between the power storage unit and a transfer target that transfers power to and from the power storage unit. The in-vehicle cutoff device includes a cutoff unit and a switching unit. The cutoff unit is provided on the conductive path and is configured to switch from a permissive state where current is permitted to flow through the conductive path to a cutoff state. The switching unit is configured to switch the cutoff unit to the cutoff state based on a result of comparison between a current flowing through a first positive-side conductive path and a second positive-side conductive path included in the conductive path and a current flowing through a first negative-side conductive path and a second negative-side conductive path included in the conductive path.

### CROSS-REFERENCE TO RELATED APPLICATIONS

This application is the U.S. national stage of PCT/JP2023/017370 filed on May 9, 2023, the content of which is incorporated herein.

### TECHNICAL FIELD

The present disclosure relates to an in-vehicle cutoff device.

### BACKGROUND

JP 2022-524031T discloses a leakage detection device for performing leakage detection. This leakage detection device includes a battery voltage sensor, a first series circuit, a second series circuit, a voltage distributor, an analog-to-digital converter, and a control unit. The battery voltage sensor is configured to measure a battery voltage between a positive terminal and a negative terminal of the battery. The first series circuit includes a first resistor and a first switch which are connected in series between a first node connected to the negative terminal and a second node which can be connected to the chassis. The second series circuit includes a second resistor and a second switch which are connected in series between the second node and a third node connected to the positive terminal. The voltage divider is connected in parallel to the first series circuit and includes a third resistor and a fourth resistor connected in series via a fourth node. The analog-to-digital converter is configured to generate a digital signal that indicates a voltage between the first node and the fourth node. The control unit is operatively connected to the battery voltage sensor, the first switch, the second switch, and the analog-to-digital converter. The control unit determines a first detection voltage based on a digital signal at a first detection time during execution of a first leakage detection mode where the first switch is controlled to be in an ON state and the second switch is controlled to be in an OFF state. The control unit determines a second detection voltage based on a digital signal at a second detection time during execution of a second leakage detection mode where the first switch is controlled to be in the OFF state and the second switch is controlled to be in the ON state. The control unit determines a first insulation resistance between the positive terminal and the chassis and a second insulation resistance between the negative terminal and the chassis based on the battery voltage, the first detection voltage, and the second detection voltage. The control unit determines a leakage current of the battery based on the first insulation resistance and the second insulation resistance.

However, the configuration of JP 2022-524031T is designed to detect a leakage while charging and discharging of the battery are suspended, and is not suited to quick detection while the battery is being charged and discharged. For example, in the configuration of JP 2022-524031T, it is necessary to switch the first switch and the second switch to the ON state alternately, but detection tends to take time due to the influence of the capacitor provided for noise suppression. For this reason, when a leakage is detected and the current is to be cut off, there is a delay in the cutoff.

It is an object of the present disclosure to provide a technique for quickly cutting off a current flowing through a conductive path when a ground fault has occurred during charging or discharging of a power storage unit mounted in a vehicle.

### SUMMARY

An in-vehicle cutoff device according to the present disclosure is an in-vehicle cutoff device configured to be mounted in a vehicle including: a power storage unit; and a conductive path provided between the power storage unit and a transfer target that performs power transfer with the power storage unit, the in-vehicle cutoff device including: a cutoff unit provided on the conductive path and configured to switch from a permissive state where current is permitted to flow through the conductive path to a cutoff state; and a switching unit configured to switch the cutoff unit to the cutoff state based on a result of comparison between a current flowing through a positive-side conductive path included in the conductive path and a current flowing through a negative-side conductive path included in the conductive path.

### Advantageous Effects

With the technique according to the present disclosure, it is possible to quickly cut off a current flowing through a conductive path when a ground fault has occurred during charging or discharging of a power storage unit mounted in a vehicle.

### BRIEF DESCRIPTION OF DRAWINGS

FIG. 1 is a configuration diagram schematically showing a vehicle, which includes an in-vehicle cutoff device according to a first embodiment, and a charging device.

### DETAILED DESCRIPTION OF PREFERRED EMBODIMENTS

Embodiments of the present disclosure will be listed and described below.

In a first aspect, an in-vehicle cutoff device configured to be mounted in a vehicle including: a power storage unit; and a conductive path provided between the power storage unit and a transfer target that performs power transfer with the power storage unit, the in-vehicle cutoff device including: a cutoff unit provided on the conductive path and configured to switch from a permissive state where current is permitted to flow through the conductive path to a cutoff state; and a switching unit configured to switch the cutoff unit to the cutoff state based on a result of comparison between a current flowing through a positive-side conductive path included in the conductive path and a current flowing through a negative-side conductive path included in the conductive path.

When a ground fault has occurred in the conductive path during charging or discharging of the power storage unit, a difference may arise between the current flowing through the positive-side conductive path and the current flowing through the negative-side conductive path. When such a difference occurs, the above-mentioned in-vehicle cutoff device can switch the cutoff unit to the cutoff state based on the comparison result of the current flowing through the positive-side conductive path and the current flowing through the negative-side conductive path. In other words, the above-mentioned in-vehicle cutoff device can quickly cut off the current flowing through the conductive path when a ground fault has occurred during charging or discharging of the power storage unit.

In a second aspect, the in-vehicle cutoff device, the switching unit switches the cutoff unit to the cutoff state based on a difference between the current flowing through the positive-side conductive path and the current flowing through the negative-side conductive path.

The above-mentioned in-vehicle cutoff device switches the cutoff unit to the cutoff state based on the difference rather than the ratio, enabling it to accurately determine a ground fault and quickly cut off the current flowing through the conductive path.

In a third aspect, the in-vehicle cutoff device according to the second aspect, the switching unit switches the cutoff unit to the cutoff state when the difference has exceeded a threshold value.

The above in-vehicle cutoff device can simplify the configuration for switching the cutoff unit to the cutoff state based on the comparison result.

In a fourth aspect, the in-vehicle cutoff device according to the second aspect, the switching unit switches the cutoff unit to the cutoff state when an integral value of the difference during a predetermined period has exceeded a threshold value.

The above in-vehicle cutoff device can switch the cutoff unit to the cutoff state when the above difference has accumulated to a certain extent during a predetermined period.

In a fifth aspect, the in-vehicle cutoff device, the switching unit switches the cutoff unit to the cutoff state when an integral value of a square of the difference during a predetermined period has exceeded a threshold value.

The above in-vehicle cutoff device can switch the cutoff unit to the cutoff state when the square of the above difference has accumulated to a certain extent during a predetermined period.

In a sixth aspect, the in-vehicle cutoff device according to the second aspect, the switching unit switches the cutoff unit to the cutoff state when Tw calculated by the following Expression (A) has exceeded a threshold value.

$$Tw = reference temperature + Δ Tw ( n ) \qquad Expression ( A )$$

$$where$$

$$Δ Tw ( n ) = Δ Tw ( n - 1 ) \times exp ( - Δ t / τ w ) + Rthw \times Rw ( n - 1 ) \times Δ I {( n - 1 )}^{2} \times ( 1 - exp ( - Δ t / τ w ) ) ;$$

ΔI(n) denotes the difference in the nth detection;
n denotes an integer of 1 or more;
Δt denotes the unit time for detecting the above difference;
τw denotes the heat dissipation time constant(s) of the conductive path;
Rthw denotes the thermal resistance (° C./W) of the conductive path;
Rw(n) denotes the resistance (Ω) of the conductive path when detected n times;

$$Rw ( n ) = Rw ( 0 ) \times ( 1 + κ w \times ( Tw - To ) ) ;$$

Rw(0) is the resistance (Ω) of the conductive path at temperature T_{O}; and
κw is the resistance temperature coefficient (/° C.) of the conductive path.

The above in-vehicle cutoff device can switch the cutoff unit to the cutoff state when Tw, which is calculated using the above difference, has exceeded the threshold value.

In a seventh aspect, the in-vehicle cutoff device according to any one of the first to the sixth aspects, the transfer target is a charging device connected to an inlet of the vehicle, the vehicle includes a voltage conversion unit provided between the inlet and the power storage unit and configured to boost a voltage input from the inlet and output the boosted voltage to the power storage unit, the conductive path includes a first conductive path provided between the inlet and the voltage conversion unit and a second conductive path provided between the voltage conversion unit and the power storage unit, the first conductive path includes a first positive-side conductive path that is a part of the positive-side conductive path and a first negative-side conductive path that is a part of the negative-side conductive path, and the switching unit switches the cutoff unit to the cutoff state based on a result of comparison between the current flowing through the first positive-side conductive path and the current flowing through the first negative-side conductive path.

In the above-mentioned in-vehicle cutoff device, when a ground fault has occurred in the second conductive path during the charging operation in which the input voltage from the charging device is boosted by the voltage conversion unit to charge the power storage unit, a difference occurs between the current flowing through the first positive-side conductive path and the current flowing through the first negative-side conductive path. When such a difference occurs, the above-mentioned in-vehicle cutoff device can switch the cutoff unit to the cutoff state based on the comparison result of the current flowing through the first positive-side conductive path and the current flowing through the first negative-side conductive path. In other words, the above-mentioned in-vehicle cutoff device can quickly cut off the current flowing through the conductive path when a ground fault has occurred during charging of the power storage unit.

### First Embodiment

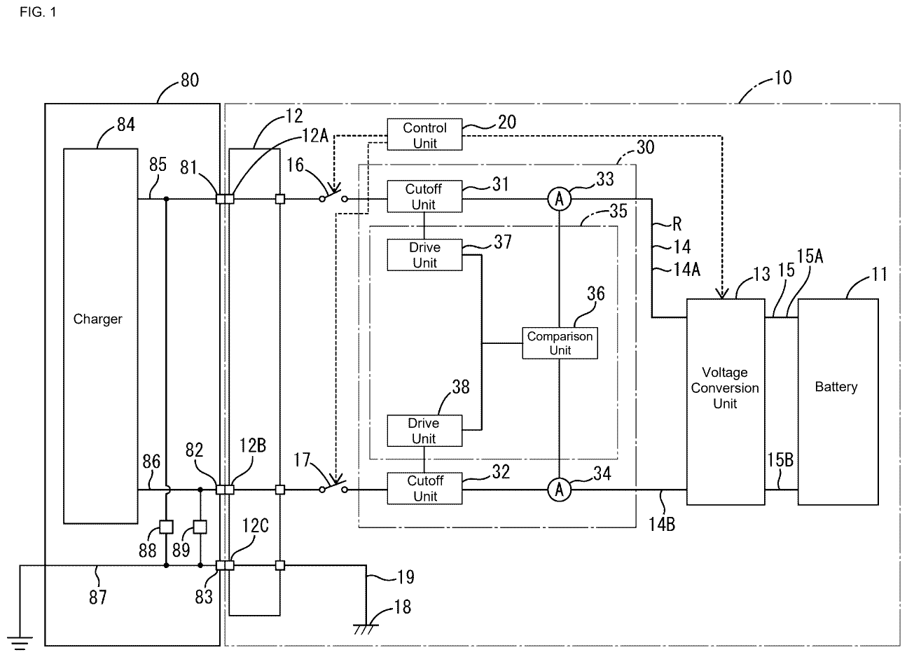

FIG. 1 shows a vehicle 10 including an in-vehicle cutoff device 30 and a charging device 80. The vehicle 10 is a vehicle such as an electric vehicle that travels using a battery 11 as the power source. The battery 11 is charged by the charging device 80 outside the vehicle 10.

The vehicle 10 includes the battery 11, an inlet 12, a voltage conversion unit 13, a conductive path R that includes a first conductive path 14 and a second conductive path 15, relays 16 and 17, a vehicle body 18, a reference conductive path 19, a control unit 20, and the in-vehicle cutoff device 30.

The battery 11 corresponds to an example of a power storage unit. The battery 11 is, for example, a high-voltage battery capable of supplying electric power to a drive motor. The motor is a motor that provides motive power to wheels of vehicle 10. The output voltage of the battery 11 when fully charged is, for example, 800 V. The battery 11 may be constituted by secondary batteries such as lithium-ion batteries or other type of power storage batteries.

The inlet 12 is connected to the charging device 80 outside the vehicle 10. Power is supplied from the charging device 80 to the inlet 12. The inlet 12 has a first terminal 12A, a second terminal 12B, and a connection portion 12C. The connection portion 12C includes a connection terminal.

The charging device 80 corresponds to an example of a transfer target. The charging device 80 is, for example, a device that supplies a DC voltage of 400 V. The charging device 80 includes a first counterpart terminal 81 to be connected to the first terminal 12A, a second counterpart terminal 82 to be connected to the second terminal 12B, and a counterpart connection portion 83 to be connected to the connection portion 12C. The counterpart connection portion 83 includes the counterpart connection terminal. The charging device 80 includes a charger 84. The charger 84 converts an AC power such as a commercial power supply into a DC power and output the DC power. The charger 84 is constituted as, for example, an off-board charger.

The charging device 80 includes a positive-side supply path 85, a negative-side supply path 86, and a protective ground wire 87. The positive-side supply path 85 and the negative-side supply path 86 are electrical paths that supply power from the charger 84 to the inlet 12. One end of the positive-side supply path 85 is electrically connected to a positive terminal of the charger 84. The other end of the positive-side supply path 85 is electrically connected to the first counterpart terminal 81. One end of the negative-side supply path 86 is electrically connected to a negative terminal of the charger 84. The other end of the negative-side supply path 86 is electrically connected to the second counterpart terminal 82. One end of the protective ground wire 87 is grounded. The other end of the protective ground wire 87 is electrically connected to the counterpart connection portion 83.

The charging device 80 includes a first SPD 88 and a second SPD 89. The first SPD 88 and the second SPD 89 are surge protective devices (SPD). The first SPD 88 is provided between the positive-side supply path 85 and the protective ground wire 87. The first SPD 88 has a function to discharge over-voltage generated in the positive-side supply path 85 to the protective ground wire 87. The second SPD 89 is provided between the negative-side supply path 86 and the protective ground wire 87. The second SPD 89 has a function to discharge over-voltage generated in the negative-side supply path 86 to the protective ground wire 87.

The charging device 80 includes a plug (not shown). The plug is connected to the inlet 12. The charging device 80 supplies a DC power to the inlet 12 via a plug.

The voltage conversion unit 13 is provided between the inlet 12 and the battery 11. The voltage conversion unit 13 performs a conversion operation in which the voltage input from the inlet 12 is boosted and output to the battery 11.

In this embodiment, the voltage conversion unit 13 performs a boost operation that boosts the voltage input from the inlet 12 and outputs the boosted voltage to the battery 11. The voltage conversion unit 13 is constituted by, for example, a DCDC converter.

A conductive path R is provided between the charging device 80 and the battery 11. The conductive path R is constituted by, for example, electric wires and bus bars. The conductive path R has the first conductive path 14 and the second conductive path 15.

The first conductive path 14 is provided between the inlet 12 and the voltage conversion unit 13. The first conductive path 14 includes a first positive-side conductive path 14A and a first negative-side conductive path 14B. One end of the first positive-side conductive path 14A is electrically connected to the first terminal 12A. The other end of the first positive-side conductive path 14A is electrically connected to the voltage conversion unit 13. One end of the first negative-side conductive path 14B is electrically connected to the second terminal 12B. The other end of the first negative-side conductive path 14B is electrically connected to the voltage conversion unit 13.

The second conductive path 15 is provided between the voltage conversion unit 13 and the battery 11. The second conductive path 15 includes a second positive-side conductive path 15A and a second negative-side conductive path 15B. One end of the second positive-side conductive path 15A is electrically connected to a high potential terminal of the battery 11. The other end of the second positive-side conductive path 15A is electrically connected to the voltage conversion unit 13. One end of the second negative-side conductive path 15B is electrically connected to a low potential terminal of the battery 11. The other end of the second negative-side conductive path 15B is electrically connected to the voltage conversion unit 13.

The first positive-side conductive path 14A and the second positive-side conductive path 15A constitute the positive-side conductive path of the conductive path R. The first negative-side conductive path 14B and the second negative-side conductive path 15B constitute the negative-side conductive path of the conductive path R.

The voltage conversion unit 13 described above converts (specifically, boosts) the voltage applied to the first conductive path 14 during the conversion operation and applies the resultant voltage to the second conductive path 15. More specifically, the voltage conversion unit 13 converts the voltage applied between the first positive-side conductive path 14A and the first negative-side conductive path 14B and applies the resultant voltage between the second positive-side conductive path 15A and the second negative-side conductive path 15B.

The relay 16 is provided on the first positive-side conductive path 14A. The relay 17 is provided on the first negative-side conductive path 14B. The relays 16 and 17 allow current to flow between the inlet 12 and the voltage conversion unit 13 when they are in the ON state. The relays 16 and 17 prevent current from flowing between the inlet 12 and the voltage conversion unit 13 when they are in the OFF state. The relays 16 and 17 may be mechanical relays having contacts, or semiconductor relays composed of semiconductor switching elements.

The reference conductive path 19 is electrically connected to the vehicle body 18. The reference conductive path 19 is electrically connected to the connection portion 12C of the inlet 12. The reference conductive path 19 is electrically connected to the protective ground wire 87 when the counterpart connection portion 83 of the charging device 80 is connected to the connection portion 12C. This electrically connects the vehicle body 18 to the protective ground wire 87.

The control unit 20 controls the voltage conversion unit 13 and the relays 16 and 17. The control unit 20 is configured to include, for example, a microcomputer. The control unit 20 is configured, for example, as an MCU (Micro Controller Unit). The control unit 20 includes an information processing unit such as a CPU and a memory unit such as a ROM or a RAM.

When the plug of the charging device 80 is not connected to the inlet 12, the control unit 20 controls the relays 16 and 17 to be in the OFF state while stopping the voltage conversion unit 13. When the plug of the charging device 80 is connected to the inlet 12, the control unit 20 switches the relays 16 and 17 to the ON state and causes the voltage conversion unit 13 to perform the conversion operation. The control unit 20, for example, boosts the voltage of 400 V applied to the first conductive path 14 to 800 V and applies the boosted voltage to the second conductive path 15. In this manner, 800 V of power is supplied to the battery 11. Furthermore, the control unit 20 determines whether the plug of the charging device 80 is connected to the inlet 12 based on a signal from the charging device 80, for example.

In the configuration described above, when the battery 11 is charged from the charging device 80, the vehicle body 18 is electrically connected to the protective ground wire 87. This makes it possible to prevent a person who has touched the vehicle body 18 from receiving an electric shock, even when a ground fault has occurred. However, for example, when a ground fault has occurred in the second conductive path 15 to which the voltage boosted by the voltage conversion unit 13 is applied, the boosted voltage will be supplied via the first conductive path 14 to the positive-side supply path 85 and the negative-side supply path 86 of the charging device 80. In this case, an unexpected over voltage may be applied to the first SPD 88 and the second SPD 89, which may cause failure. If the second SPD 89 fails, for example, there is a risk of the negative-side supply path 86 becoming short-circuited via the second SPD 89 to the protective ground wire 87. If the negative-side supply path 86 is short-circuited to the protective ground wire 87, an unexpectedly large current may flow through the protective ground wire 87, which may melt the protective ground wire 87. The object of the in-vehicle cutoff device 30 is to quickly cut off the power path in this situation before the protective ground wire 87 melts.

The in-vehicle cutoff device 30 is a device installed in the vehicle 10. The in-vehicle cutoff device 30 cuts off the current flowing through the conductive path R when a ground fault has occurred in the conductive path R. The in-vehicle cutoff device 30 has cutoff units 31 and 32, current detection units 33 and 34, a switching unit 35, a comparison unit 36, and drive units 37 and 38.

The cutoff unit 31 is provided in the first positive-side conductive path 14A. The cutoff unit 32 is provided in the first negative-side conductive path 14B. The cutoff units 31 and 32 switch from a permissive state to a cutoff state in response to a drive signal being input. The permissive state is a state in which current is allowed to flow through the first conductive path 14. The cutoff state is a state where the flow of current on the first conductive path 14 is cut off. The cutoff unit 31 may use a non-recoverable configuration where it is not possible to return to the permissive state after entering the cutoff state, or may use a recoverable configuration where the permissive state can be restored. One example of a non-recoverable configuration is a pyrotechnic cutoff device (for example, a PYROFUSE (registered trademark)) that physically cuts off the first conductive path 14 in response to a drive signal being input into the input unit 31A. One example of a recoverable configuration is a switch. The switch may be a mechanical switch with contacts, or a semiconductor switch, such as a MOSFET or an IGBT.

The current detection unit 33 detects the current flowing through the first positive-side conductive path 14A. The current detection unit 33 outputs a detection value with the current flowing from the charging device 80 to the battery 11 as positive. The current detection unit 34 detects the current flowing through the first negative-side conductive path 14B. The current detection unit 34 outputs a detection value with the current flowing from the battery 11 to the charging device 80 as positive. The detection values of the current detection units 33 and 34 are input to the comparison unit 36. The current detection units 33 and 34 may be a contactless type that is disposed in a contactless manner on the first conductive path 14, or a contact type that is disposed in contact with the first conductive path 14. A contactless type is, for example, constituted by a magnetic sensor such as a Hall element. A contact type is, for example, constituted by a shunt resistor and a differential amplifier that amplifies and outputs a voltage across both ends of the shunt resistor.

The switching unit 35 switches the cutoff units 31 and 32 to the cutoff state based on the comparison result (in this embodiment, the difference) between the current flowing through the first positive-side conductive path 14A and the current flowing through the first negative-side conductive path 14B. The switching unit 35 includes the comparison unit 36 and the drive units 37 and 38.

The comparison unit 36 compares the current flowing through first positive-side conductive path 14A with the current flowing through first negative-side conductive path 14B. Specifically, the comparison unit 36 calculates the difference between the value of the current flowing through the first positive-side conductive path 14A and the value of the current flowing through the first negative-side conductive path 14B. The comparison unit 36 determines whether or not the calculated difference exceeds a predetermined threshold value. When the comparison unit 36 determines that the difference has exceeded the threshold value, the comparison unit 36 outputs an instruction signal to the drive units 37 and 38. If the comparison unit 36 determines that the difference does not exceed the threshold, the comparison unit 36 does not output the instruction signal.

Upon receiving the instruction signal, the drive unit 37 outputs a drive signal and switches the cutoff unit 31 to the cutoff state. Upon receiving the instruction signal, the drive unit 38 outputs a drive signal and switches the cutoff unit 32 to the cutoff state.

The in-vehicle cutoff device 30 operates as follows. When the relays 16 and 17 switch to the ON state and the voltage conversion unit 13 performs a boost operation, power from the charging device 80 is supplied to the battery 11. At this time, current flows from the charging device 80 to the battery 11 through the first positive-side conductive path 14A and the second positive-side conductive path 15A, and current flows from the battery 11 to the charging device 80 through the first negative-side conductive path 14B and the second negative-side conductive path 15B.

When power is being supplied normally from the charging device 80 to the battery 11, the current flowing through the first positive-side conductive path 14A and the current flowing through the first negative-side conductive path 14B are approximately equal. Therefore, the comparison unit 36 determines that the difference between the current flowing through the first positive-side conductive path 14A and the current flowing through the first negative-side conductive path 14B does not exceed the threshold value, and does not output an instruction signal. As a result, the cutoff units 31 and 32 are maintained in the permissive state.

When a ground fault has occurred in the second positive-side conductive path 15A, the current flowing through the first negative-side conductive path 14B becomes larger than the current flowing through the first positive-side conductive path 14A. When the comparison unit 36 determines that the difference between the current flowing through the first negative-side conductive path 14B and the current flowing through the first positive-side conductive path 14A (in this embodiment, the difference obtained by subtracting the current flowing through the first positive-side conductive path 14A from the current flowing through the first negative-side conductive path 14B) has exceeded a threshold value, the comparison unit 36 outputs an instruction signal. As a result, the drive unit 37 switches cutoff unit 31 to the cutoff state, and the drive unit 38 switches the cutoff unit 32 to the cutoff state. In this manner, the current flowing through the first conductive path 14 is cut off.

The following description relates to the effects of the in-vehicle cutoff device 30 of the first embodiment. In the in-vehicle cutoff device 30, when a ground fault occurs in the second conductive path 15 during the charging operation in which the input voltage from the charging device 80 is boosted by the voltage conversion unit 13 to charge the battery 11, a difference occurs between the current flowing through the first positive-side conductive path 14A and the current flowing through the first negative-side conductive path 14B. When such a difference occurs, the in-vehicle cutoff device 30 can switch the cutoff units 31 and 32 to the cutoff state based on the difference between the current flowing through the first negative-side conductive path 14B and the current flowing through the first positive-side conductive path 14A. In other words, the in-vehicle cutoff device 30 can quickly cut off the current flowing through conductive path R when a ground fault occurs during charging of battery 11.

### Second Embodiment

In the first embodiment, when the difference between the current flowing through the first negative-side conductive path 14B and the current flowing through the first positive-side conductive path 14A exceeded a threshold value, the switching unit 35 switched the cutoff units 31 and 32 to the cutoff state. In contrast, a second embodiment describes a configuration in which the switching unit 35 switches the cutoff units 31 and 32 to the cutoff state when the integral value of the above difference during a predetermined period has exceeded a threshold value. Since the configuration of the second embodiment is the same as that shown in FIG. 1, the second embodiment will be described with reference to FIG. 1.

The switching unit 35 of the in-vehicle cutoff device 30 of the second embodiment switches the cutoff units 31 and 32 to the cutoff state when the integral value of the difference between the current flowing through the first negative-side conductive path 14B and the current flowing through the first positive-side conductive path 14A (in this embodiment, the difference obtained by subtracting the current flowing through the first positive-side conductive path 14A from the current flowing through the first negative-side conductive path 14B) during a predetermined period has exceeded a threshold value.

The comparison unit 36 calculates the integral value of the difference between the current flowing through the first negative-side conductive path 14B and the current flowing through the first positive-side conductive path 14A during a predetermined period. The predetermined period may be, for example, a fixed period of time in the immediate past, or may be the period from when a measurement start condition was satisfied.

The measurement start condition may be when the current flowing through the conductive path R (e.g., the current detected by the current detection unit 33 or the current detected by the current detection unit 34) has exceeded a predetermined measurement start current. The measurement start current is preferably a direct current that flows without issue, and is preferably, for example, a current tolerable by the first SPD 88 and the second SPD 89.

As another example, the measurement start condition may be when the increase in the difference between the current flowing through the first negative-side conductive path 14B and the current flowing through the first positive-side conductive path 14A has exceeded a determination value. In this case, the comparison unit 36 calculates the above difference for each predetermined determination period, calculates the increase in the above difference for each determination period, and determines whether or not the calculated increase exceeds the determination value.

The predetermined period that starts when the measurement start condition is satisfied may end when the measurement end condition is satisfied. In other words, when the measurement end condition is satisfied, the integral value may be cleared. The measurement end condition may be, for example, when the current flowing through the conductive path R (e.g., the current detected by the current detection unit 33 or the current detected by the current detection unit 34) falls below a predetermined measurement end current. The measurement end current may be the same as or different from the measurement start current.

The comparison unit 36 determines whether the calculated integral value exceeds the threshold value. When the comparison unit 36 determines that the integral value has exceeded the threshold value, the comparison unit 36 outputs an instruction signal to the drive units 37 and 38. When the comparison unit 36 determines that the integral value has not exceeded the threshold value, the comparison unit 36 does not output an instruction signal.

Upon receiving an instruction signal, the drive unit 37 outputs a drive signal and switches the cutoff unit 31 to the cutoff state. Upon receiving an instruction signal, the drive unit 38 outputs a drive signal and switches the cutoff unit 32 to the cutoff state.

The current flowing through the first SPD 88 and the second SPD 89 varies significantly depending on the voltage applied to the voltage across both ends thereof. For this reason, it is preferable that the cutoff units 31 and 32 be cutoff at less than or equal to the allowable losses of the first SPD 88 and the second SPD 89. The in-vehicle cutoff device 30 of the second embodiment can cut off the current flowing through the first conductive path 14 and the second conductive path 15 before the first SPD 88 and the second SPD 89 fail, when the threshold is set to be less than or equal to the allowable loss of the first SPD 88 and the second SPD 89.

### Third Embodiment

In the first embodiment, when the difference between the current flowing through the first negative-side conductive path 14B and the current flowing through the first positive-side conductive path 14A has exceeded a threshold value, the switching unit 35 switched the cutoff units 31 and 32 to the cutoff state. In contrast to this, a third embodiment describes a configuration in which the switching unit 35 switches the cutoff units 31 and 32 to the cutoff state when the integral value of the square of the above difference during a predetermined period has exceeded a threshold value. Since the configuration of the third embodiment is the same as that shown in FIG. 1, the third embodiment will be described with reference to FIG. 1.

In the third embodiment, the switching unit 35 of the in-vehicle cutoff device 30 switches the cutoff units 31 and 32 to the cutoff state when the integral value of the square of the difference between the current flowing through the first negative-side conductive path 14B and the current flowing through the first positive-side conductive path 14A (in this embodiment, the difference obtained by subtracting the current flowing through the first positive-side conductive path 14A from the current flowing through the first negative-side conductive path 14B) during a predetermined period has exceeded a threshold value.

The comparison unit 36 calculates the integral value of the square of the difference between the current flowing through the first negative-side conductive path 14B and the current flowing through the first positive-side conductive path 14A during a predetermined period. The predetermined period may be, for example, a fixed period of time in the immediate past, or the period from when the measurement start condition was satisfied.

The measurement start condition may be when the current flowing through the conductive path R (e.g., the current detected by the current detection unit 33 or the current detected by the current detection unit 34) has exceeded a predetermined measurement start current. The measurement start current is preferably a direct current that flows without issue, such as a current that does not cause the protective ground wire 87 to start smoking.

As another example, the measurement start condition may be when the increase in the difference between the current flowing through the first negative-side conductive path 14B and the current flowing through the first positive-side conductive path 14A has exceeded the determination value. In this case, the comparison unit 36 calculates the above difference for each predetermined determination period, calculates the increase in the above difference for each determination period, and determines whether or not the calculated increase has exceeded the determination value.

The predetermined period that starts when the measurement start condition is satisfied may end when the measurement end condition is satisfied. In other words, when the measurement end condition is satisfied, the integral value may be cleared. The measurement end condition may be, for example, when the current flowing through the conductive path R (e.g., the current detected by the current detection unit 33 or the current detected by the current detection unit 34) falls below a predetermined measurement end current. The measurement end current may be the same as or different from the measurement start current.

The comparison unit 36 determines whether or not the calculated integral value exceeds the threshold value. When the comparison unit 36 determines that the integral value has exceeded the threshold value, the comparison unit 36 outputs an instruction signal to the drive units 37 and 38. When the comparison unit 36 determines that the integral value has not exceeded the threshold value, the comparison unit 36 does not output an instruction signal.

Upon receiving the instruction signal, the drive unit 37 outputs a drive signal and switches the cutoff unit 31 to the cutoff state. Upon receiving the instruction signal, the drive unit 38 outputs a drive signal and switches the cutoff unit 32 to the cutoff state.

In the third embodiment, the in-vehicle cutoff device 30 can cut off the current flowing through the first conductive path 14 and the second conductive path 15 before the protective ground wire 87 starts smoking when the threshold is set such that the protective ground wire 87 does not smoke.

### Fourth Embodiment

In the first embodiment, when the difference between the current flowing through the first negative-side conductive path 14B and the current flowing through the first positive-side conductive path 14A has exceeded a threshold value, the switching unit 35 switched the cutoff units 31 and 32 to the cutoff state. In contrast, a fourth embodiment describes a configuration in which the cutoff units 31 and 32 are switched to the cutoff state based on a temperature Tw calculated using the above difference. Since the configuration of the fourth embodiment is the same as that shown in FIG. 1, the fourth embodiment will be described with reference to FIG. 1.

The switching unit 35 of the in-vehicle cutoff device 30 in the fourth embodiment switches the cutoff units 31 and 32 to the cutoff state when Tw calculated by the following expression (A) has exceeded the threshold value.

$$Tw = reference temperature + Δ Tw ( n ) \qquad Expression ( A )$$

$$where$$

$$Δ Tw ( n ) = Δ Tw ( n - 1 ) \times exp ( - Δ t / τ w ) + Rthw \times Rw ( n - 1 ) \times Δ I {( n - 1 )}^{2} \times ( 1 - exp ( - Δ t / τ w ) ) ;$$

ΔI(n) denotes the above difference detected in the nth detection (in this embodiment, the difference obtained by subtracting the current flowing through the first negative-side conductive path 14B from the current flowing through the first positive-side conductive path 14A);
n denotes an integer greater than or equal to 1;
Δt denotes the unit time for detecting the above difference;
τw denotes the heat dissipation time constant(s) of the first conductive path 14;
Rthw denotes the thermal resistance (° C./W) of the first conductive path 14;
Rw(n) denotes the resistance (Ω) of the first conductive path 14 when detected n times;

$$Rw ( n ) = Rw ( 0 ) \times ( 1 + κ w \times ( Tw - To ) ) ;$$

Rw(0) denotes the resistance (Ω) of the first conductive path 14 at temperature T_{O}; and
κW denotes the resistance temperature coefficient (/° C.) of the first conductive path 14.

Furthermore, ΔTw(n) corresponds to the content obtained by substituting ΔI(n) for I(n) in Expression 1 disclosed in paragraph of JP 2009-130944A.

The in-vehicle cutoff device 30 of the fourth embodiment can switch the cutoff units 31 and 32 to the cutoff state when Tw calculated using the above difference has exceeded the threshold value.

### OTHER EMBODIMENTS

The present disclosure is not limited to the embodiments described above and depicted in the drawings. For example, the features of the embodiments described above and below may be combined in any manner as long as no contradiction arises. Any feature of the embodiments described above or below may be omitted unless clearly indicated as essential. Additionally, the embodiments described above may be modified as follows.

Although the transfer target was the charging device 80 in the above embodiments, the transfer target may be another device. The transfer target may also be a device installed in vehicle 10. The transfer target may also be a device that receives power from the battery 11 (e.g., a load).

Although the cutoff units 31 and 32 were provided on both the first positive-side conductive path 14A and the first negative-side conductive path 14B in the above embodiments, the cutoff units 31 and 32 may be provided on only one thereof.

In the first embodiment described above, the switching unit 35 was configured to switch the cutoff units 31 and 32 to the cutoff state when the difference obtained by subtracting the current flowing through the first positive-side conductive path 14A from the current flowing through the first negative-side conductive path 14B has exceeded a threshold value. In contrast to this, the switching unit 35 may also be configured to switch the cutoff units 31 and 32 to the cutoff state when either the difference obtained by subtracting the current flowing through the first negative-side conductive path 14B from the current flowing through the first positive-side conductive path 14A has exceeded a threshold value. Alternatively, the switching unit 35 may be configured to switch the cutoff units 31 and 32 to the cutoff state when the difference obtained by subtracting the current flowing through the first positive-side conductive path 14A from the current flowing through the first negative-side conductive path 14B or the difference obtained by subtracting the current flowing through the first negative-side conductive path 14B from the current flowing through the first positive-side conductive path 14A has exceeded a threshold value.

In the second embodiment described above, the switching unit 35 was configured to switch the cutoff units 31 and 32 to the cutoff state when the integral value of the difference obtained by subtracting the current flowing through the first positive-side conductive path 14A from the current flowing through the first negative-side conductive path 14B during a predetermined period has exceeded a threshold value. In contrast to this, the switching unit 35 may be configured to switch the cutoff units 31 and 32 to the cutoff state when the integral value of the difference obtained by subtracting the current flowing through the first negative-side conductive path 14B from the current flowing through the first positive-side conductive path 14A during a predetermined period exceeds a threshold value. Alternatively, the switching unit 35 may be configured to switch the cutoff units 31 and 32 to the cutoff state when either the integral value of the difference obtained by subtracting the current flowing through the first positive-side conductive path 14A from the current flowing through the first negative-side conductive path 14B during a predetermined period or the integral value of the difference obtained by subtracting the current flowing through the first negative-side conductive path 14B from the current flowing through the first positive-side conductive path 14A during a predetermined period has exceeded a threshold value.

In the third embodiment described above, the switching unit 35 was configured to switch the cutoff units 31 and 32 to the cutoff state when the integral value of the square of the difference obtained by subtracting the current flowing through the first positive-side conductive path 14A and the current flowing through the first negative-side conductive path 14B has exceeded a threshold value. In contrast to this, the switching unit 35 may be configured to switch the cutoff units 31 and 32 to the cutoff state when the integral value of the square of the difference obtained by subtracting the current flowing through the first negative-side conductive path 14B from the current flowing through the first positive-side conductive path 14A during a predetermined period has exceeded a threshold value. Alternatively, the switching unit 35 may be configured to switch the cutoff unit 31, 32 to the cutoff state when either the integral during a predetermined period of the square of the difference obtained by subtracting the current flowing through the first positive-side conductive path 14A from the current flowing through the first negative-side conductive path 14B, or the integral during a predetermined period of the square of the difference obtained by subtracting the current flowing through the first negative-side conductive path 14B from the current flowing through the first positive-side conductive path 14A exceeds a threshold value.

In the fourth embodiment, Tw was calculated using the difference obtained by subtracting the current flowing through the first positive-side conductive path 14A from the current flowing through the first negative-side conductive path 14B. In contrast to this, Tw may be calculated using a difference obtained by subtracting the current flowing through the first negative-side conductive path 14B from the current flowing through the first positive-side conductive path 14A. Tw may include Tw1 calculated using a difference obtained by subtracting the current flowing through the first positive-side conductive path 14A from the current flowing through the first negative-side conductive path 14B, and Tw2 calculated using a difference obtained by subtracting the current flowing through the first negative-side conductive path 14B from the current flowing through the first positive-side conductive path 14A. In this case, the switching unit 35 may be configured to switch the cutoff units 31 and 32 to the cutoff state when one of Tw1 and Tw2 has exceeded the threshold value.

The embodiments disclosed here are to be considered in all respects as illustrative and not limiting. The scope of the present disclosure is indicated by the claims rather than being limited to the foregoing embodiments, and all changes which come within the meaning and range of equivalency of the claims are intended to be embraced therein.

1. An in-vehicle cutoff device configured to be mounted in a vehicle including: a power storage unit; and a conductive path provided between the power storage unit and a transfer target that performs power transfer with the power storage unit, the in-vehicle cutoff device comprising:
a cutoff unit provided on the conductive path and configured to switch from a permissive state where current is permitted to flow through the conductive path to a cutoff state; and
a switching unit configured to switch the cutoff unit to the cutoff state based on a result of comparison between a current flowing through a positive-side conductive path included in the conductive path and a current flowing through a negative-side conductive path included in the conductive path.

2. The in-vehicle cutoff device according to claim 1, wherein the switching unit switches the cutoff unit to the cutoff state based on a difference between the current flowing through the positive-side conductive path and the current flowing through the negative-side conductive path.

3. The in-vehicle cutoff device according to claim 2, wherein the switching unit switches the cutoff unit to the cutoff state when the difference has exceeded a threshold value.

4. The in-vehicle cutoff device according to claim 2, wherein the switching unit switches the cutoff unit to the cutoff state when an integral value of the difference during a predetermined period has exceeded a threshold value.

5. The in-vehicle cutoff device according to claim 2, wherein the switching unit switches the cutoff unit to the cutoff state when an integral value of a square of the difference during a predetermined period has exceeded a threshold value.

6. The in-vehicle cutoff device according to claim 2,
wherein the switching unit switches the cutoff unit to the cutoff state when Tw calculated by the following Expression (A) has exceeded a threshold value.
$$Tw = reference temperature + Δ Tw ( n ) \qquad Expression ( A )$$
where
$$Δ Tw ( n ) = Δ Tw ( n - 1 ) \times exp ( - Δ t / τ w ) + Rthw \times Rw ( n - 1 ) \times Δ I ( n - 1 ) 2 \times ( 1 - exp ( - Δ t / τ w ) ) ;$$
ΔI(n) denotes the difference in the nth detection;
n denotes an integer of 1 or more;
Δt denotes the unit time for detecting the above difference;
τw denotes the heat dissipation time constant(s) of the conductive path;
Rthw denotes the thermal resistance (° C./W) of the conductive path;
Rw(n) denotes the resistance (Ω) of the conductive path when detected n times;
$$Rw ( n ) = Rw ( 0 ) \times ( 1 + κ w \times ( Tw - To ) ) ;$$
Rw(0) is the resistance (Ω) of the conductive path at temperature T_{O}; and
κw is the resistance temperature coefficient (/° C.) of the conductive path.

7. The in-vehicle cutoff device according to claim 1,
wherein the transfer target is a charging device connected to an inlet of the vehicle,
the vehicle includes a voltage conversion unit provided between the inlet and the power storage unit and configured to boost a voltage input from the inlet and output the boosted voltage to the power storage unit,
the conductive path includes a first conductive path provided between the inlet and the voltage conversion unit and a second conductive path provided between the voltage conversion unit and the power storage unit,
the first conductive path includes a first positive-side conductive path that is a part of the positive-side conductive path and a first negative-side conductive path that is a part of the negative-side conductive path, and
the switching unit switches the cutoff unit to the cutoff state based on a result of comparison between the current flowing through the first positive-side conductive path and the current flowing through the first negative-side conductive path.
